(19) United States
(12) Patent Application Publication
(10) Pub. No.: US 2007/0051524 A1
(43) Pub. Date: Mar. 8, 2007

(54) Process and apparatus for manufacturing structures guiding electromagnetic waves

(75) Inventors: Olaf Mientkewitz, Ronnenberg (DE); Martin Greiner, Hemmingen (DE); Erhard Mahlandt, Laatzen (DE)

Correspondence Address: SUGHRUE MION, PLLC, 2100 PENNSYLVANIA AVENUE, N.W., SUITE 800, WASHINGTON, DC, 20037, US

(73) Assignee: ALCATEL

(21) Appl. No.: 11/514,880

(22) Filed: Sep. 5, 2006

(30) Foreign Application Priority Data
Sep. 6, 2005 (EP) 05291837.2

(51) Int. Cl. H01B 11/18; C23C 4/08; C23C 16/00

(52) U.S. Cl. 174/28; 427/250; 427/455; 118/715

(57) ABSTRACT

A process for manufacturing structures for guiding electromagnetic waves, such as telecommunication cables, comprising a least a conductive layer for transmission of radio frequency waves, said conductive layer being formed by means of cold gas spraying techniques. An apparatus for manufacturing structures for guiding electromagnetic waves and a cable manufactured according to such process.

### BACKGROUND OF THE INVENTION

The invention is based on a priority application EP 05291837.2 which is hereby incorporated by reference.

The present invention relates generally to structures guiding electromagnetic waves and particularly to telecommunication cables comprising a conductive layer for transmission of radio frequency waves and a manufacturing method thereof.

Coaxial cables and other radio frequency cables are known in the art for transmitting high frequency signals. A conventional coaxial cable is formed out of an inner conductor, a dielectric material, and an outer conductor. The conductors may be tubular or solid. The two conductors are made of metal or another electrically conductive material and are disposed concentrically with the dielectric material disposed between the two. If necessary, one or more additional protective coatings of an electrically insulating material can be provided on the outer conductor.

As it is known in the art, at radio frequencies, particularly at frequencies above 1 MHz, the current flowing through the cable conductors tends to flow only directly beneath the surfaces of said conductors. This is commonly known as a “skin effect”. More particularly, current flows through and directly beneath an inside surface of the outer conductor and an outside surface of the inner conductor.

Each conductor may be manufactured by known methods. For example U.S. Pat. No. 6,717,493 discloses a radio frequency coaxial cable with clad conductors formed in the same manner. The tubular conductors are formed from a sheet of two strips of material, a base layer formed of a relatively higher conductivity material and a bulk layer formed of a relatively lower conductivity material. The higher conductivity material may be copper while the lower conductivity material may be aluminium. To form either the inner conductor and the outer conductor the sheet is folded or curved and the edges brought together and welded by conventional techniques. U.S. patent Application 2001/0008187 discloses a coaxial cable in which the outer conductor comprises an electro-conductive lacquer layer and preferably a metal layer applied to said lacquer layer. The central conductor provided with an electrically insulating layer is passed through a solution of an electro-conductive lacquer and preferably a thin metal layer is subsequently applied by means of electroless deposition in a liquid or by passing a cable through a solder bath of tin/lead.

Said cables and manufacturing methods thereof present disadvantages, for example, the manufacture of said cables is complex and slow and the cables are expensive due to the high quantity of conductive material used.

### SUMMARY OF THE INVENTION

It is the object of the present invention to provide a process and apparatus for manufacturing structures guiding electromagnetic waves which solves the aforementioned problems.

The object is achieved by a process for manufacturing structures for guiding electromagnetic waves, such as telecommunication cables, comprising at least a conductive layer for transmission of radio frequency waves using cold gas spraying for forming said conductive layer for transmission of said radio frequency waves; by an apparatus for manufacturing structures for guiding electromagnetic waves, such as telecommunication cables, the electromagnetic waves comprising at least a conductive layer for transmission of radio frequency waves, and the apparatus comprising at least two wheels rotating at a certain velocity in order to move a conductor or cable at a certain line speed, and at least one spray nozzle for applying a coating powder to the moving conductor or cable using cold gas spraying techniques; and by a structure for guiding electromagnetic waves comprising at least a conductive layer for transmission of radio frequency waves, wherein said conductive layer for transmission of radio frequency waves is a cold gas sprayed layer.

The manufacturing process according to the invention is based on the use of cold gas spraying for forming a thin, dense and adhesive conductive layer for transmission of radio frequency waves. Said conductive layer may be applied to form, for example, either the inner conductor conductive layer or the outer conductor of a coaxial cable. The outer conductor is realized by providing a cold gas sprayed layer of conductive material over the cable dielectric material.

A method and apparatus for cold gas spraying is already known from EP Patent Application 0 484 533, in which spray particles are accelerated to high speeds in a cold gas spray gun in a “cold” gas jet. The coating is formed by the impact of the particles with high kinetic energy on the work piece. Upon impact, the particles that do not melt in the “cold” gas jet form a dense and tightly adhering layer, the plastic deformation and the resulting local heat release providing for cohesion and adhesion of the sprayed layer to the work piece.

According to the invention, it has been found that the use of cold gas spraying for manufacturing of structures guiding electromagnetic waves has advantages compared with state of the art manufacture of coaxial cables. Conductive layers produced with cold gas spraying do not need the use of vacuum, present good adhesion to metals or polymers and allow thin and dense structures providing a conductivity of at least 60% the conductivity of the traditional solid metal conductor made of copper or silver. The manufacture costs of such cables and structures guiding electromagnetic waves with cold sprayed layers are thus lower due to the use of less conductive material e.g. copper or silver. The cables and other structures for guiding electromagnetic waves produced according to the invention take advantage of the observed fact that only little conductive material is needed for the transmission of radio frequency waves.

The invention also relates to an apparatus for manufacturing structures guiding electromagnetic waves. The apparatus according to the invention comprises preferably at least two wheels in charge of guiding and moving the cable and one or more spray nozzles in charge of applying the coating powder to said moving cable. In a first preferred embodiment three or more fixed spray nozzles apply the coating powder to the cable and in a second preferred embodiment only one spray nozzle is used which rotates around the cable.

The inventive process and apparatus of the invention enables the manufacture of coaxial cable in a simple, reliable and efficient manner. When the manufacturing process consists only on providing the outer conductor on the cable insulator then rates higher than two meters per minute are possible.

Additionally, the invention relates also to a structure for guiding electromagnetic waves such as a coaxial cable in which the inner and/or outer conductor comprises a cold sprayed conductive layer. Said applied metal layer has a conductivity of more than 60% of the solid metal.

Further advantageous configurations of the invention emerge from the dependent claims, the following description and the drawings.

### BRIEF DESCRIPTION OF THE DRAWINGS

An embodiment example of the invention is now explained with the aid of FIGS. 1 to 4.

FIG. 1 illustrates a first preferred embodiment of an apparatus for manufacturing structures for guiding electromagnetic waves according to the invention.

FIG. 2 shows a detailed view of the fixed spray nozzles used in FIG. 1.

FIG. 3 illustrates a second preferred embodiment of an apparatus for manufacturing structures for guiding electromagnetic waves according to the invention.

FIG. 4 shows a cross-sectional view of a structure for guiding electromagnetic waves according to the invention.

### DETAILED DESCRIPTION OF THE DRAWINGS

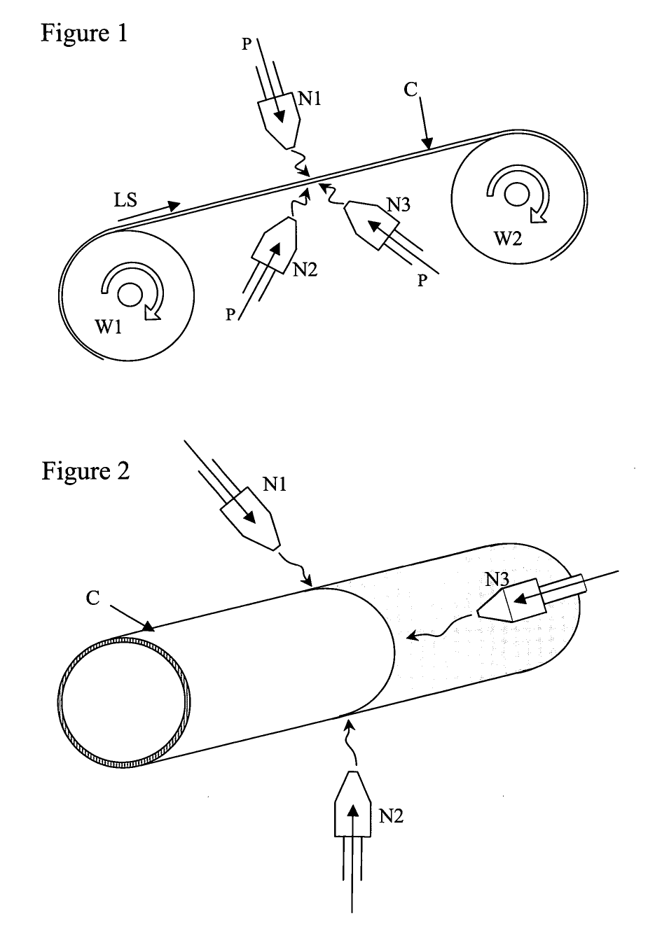

FIG. 1 shows a first embodiment of an apparatus for manufacturing structures for guiding electromagnetic waves according to the invention. The apparatus applied to the production of cables C for transmission of radio frequency electrical waves comprises two wheels W1 and W2 rotating at a certain velocity in order to move the cable at a certain line speed LS. The apparatus also comprises three nozzles N1 to N3 which apply the coating powder to the moving cable using cold gas spraying techniques.

The cable C is guided from one wheel to the other and passing a fixed structure comprising three spray nozzles. The choice of process parameters, especially the range of gas velocity may be on the range from 450 m/s to 1600 m/s and resulting the velocity of powder P. Particle sizes in the spray may be chosen in the range from 2 μm up to 35 μm. The layer thickness is adjusted by setting the line speed LS and the spray gas velocity.

Although the first embodiment shows only a three fixed nozzle spray structure, the number of nozzles may be varied from two to a larger number depending on the spray pattern of the nozzles used.

FIG. 1 only shows a manufacturing process in which only one cold gas spray layer is applied to a cable C. In cases in which more than one cold gas spray layer shall be applied to the cable more wheels or more nozzle structures may be applied in series. As already mentioned, it is to be understood that the cold gas sprayed layer can be applied to different elements of the cable, i.e. a first layer could be applied for the inner conductor of the cable according to the invention, then such inner conductor would be covered, for example by extrusion or any other means, with a dielectric material and in a next step another conductive layer could be applied to the dielectric outer surface also according to the invention; finally such cable structure could be covered by an outer protective jacket made of for example of a synthetic resin.

FIG. 2 shows a detailed view of the three fixed spray nozzle configuration N1 to N3 which apply a cold gas layer to a tubular cable C. The cable C may be a tubular metal conductor over which a cold spray layer of high conductivity is being applied or may be a conductor with a dielectric coating made of e.g. polyethylene, polypropylene or polyetheretherketon over which a cold spray layer is applied.

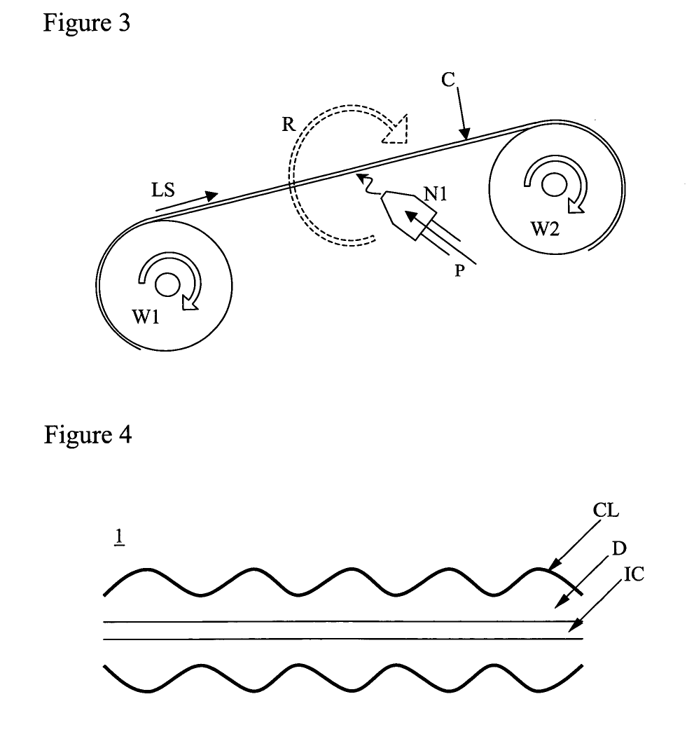

FIG. 3 shows a second embodiment of an apparatus for manufacturing structures for guiding electromagnetic waves according to the invention. The apparatus applied to the production of cables C for transmission of radio frequency electrical waves comprises two wheels W1 and W2 rotating at a certain velocity in order to move the cable at a certain line speed LS. The apparatus also comprises one nozzle N1 which applies the coating powder to the moving cable using cold gas spraying techniques. The nozzle N1 rotates in a certain direction R around the cable C in order to cover the whole surface of the cable. The high conductivity cold gas spray layer thickness is adjusted by setting the line speed LS, the speed of rotation R, and the spray gas velocity.

Although FIG. 3 shows only one nozzle rotating around the cable C, it is understood that there may be rotating nozzle configuration variants in which two or more nozzles move around the cable by a certain angle.

FIG. 4 shows a cross-sectional view of a structure for guiding electromagnetic waves 1 according to the invention, in particular a coaxial cable comprising an inner conductor IC, a dielectric D having a wave-like outer surface and a metal conductive layer CL applied to said outer dielectric surface by means of a cold gas spraying process. Alternatively, other coaxial cable dielectric surface structures and forms can also be covered by cold gas spraying techniques and devices for applying conductive cold gas sprayed layer according to the invention.

While the principles of the invention have been described above in connection with specific structures for guiding electromagnetic waves such as telecommunications cables, it is to be understood that the scope of the invention is not limited to such cables and could comprise also the production of antennas or other structures for guiding radio waves.

1. Process for manufacturing structures for guiding electromagnetic waves, such as telecommunication cables, comprising at least a conductive layer for transmission of radio frequency waves, by using cold gas spraying for forming said conductive layer for transmission of said radio frequency waves.

2. The process of claim 1 wherein the conductive layer is applied over a metal tubular or solid conductor, such as an inner conductor of a coaxial cable.

3. The process of claim 1 wherein the conductive layer is applied over a structure with a layer of dielectric material such as polyethylene, polypropylene or polyetheretherketon.

4. The process of claim 1 wherein the conductive layer provides a conductivity of at least 60% of the conductivity of the pure solid material.

5. The process of claim 1 wherein the conductive cold gas spray layer is applied by a fixed spray nozzle configuration, with at least two nozzles, around a conductor or cable moving with a certain line speed.

6. The process of claim 1 wherein the conductive cold gas spray layer is applied by one or more spray nozzles rotating a certain angle around a conductor or cable moving with a certain line speed.

7. The process of claim 5 wherein the conductive cold gas spray layer thickness is adjusted by setting the line speed and the spray gas velocity of the spray nozzles.

8. The process of claim 6 wherein the conductive cold gas spray layer thickness is adjusted by setting the speed of rotation of the spray nozzles.

9. Apparatus for manufacturing structures for guiding electromagnetic waves, such as telecommunication cables, comprising a least a conductive layer for transmission of radio frequency waves, the apparatus comprising at least two wheels rotating at a certain velocity in order to move a conductor or cable at a certain line speed, and at least one spray nozzle for applying a coating powder to the moving conductor or cable using cold gas spraying techniques.

10. The apparatus of claim 9 comprising one or more spray nozzles located around the moving conductor or cable, the spray nozzle or nozzles rotating a certain angle around the conductor or cable.

11. The apparatus of claim 9 comprising at least two spray nozzles located around the moving conductor or cable, the nozzles being in a fixed position and separated a certain angle from each other.

12. Structure for guiding electromagnetic waves comprising at least a conductive layer for transmission of radio frequency waves, such as a coaxial or triaxial cable, wherein said conductive layer for transmission of radio frequency waves is a cold gas sprayed layer.
